(19) United States
(12) Patent Application Publication
(10) Pub. No.: US 2008/0006839 A1
(43) Pub. Date: Jan. 10, 2008

(54) LIGHT EMITTING DEVICE AND METHOD FOR MANUFACTURING THE SAME

(76) Inventor: SAN BAO LIN, TAOYUAN COUNTY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/768,396

(22) Filed: Jun. 26, 2007

(30) Foreign Application Priority Data
Jul. 4, 2006 (TW) 095124305

(51) Int. Cl. H01L 33/00

(52) U.S. Cl. 257/98; 438/27; 257/E33.061

(57) ABSTRACT

A light emitting device and method for manufacturing the same are provided. Accordingly, the device comprises a fixture disposed on a submoumt; an inner space formed within the fixture for containing at least one light emitting diode; a fluorescent layer disposed into the inner space to cover the light emitting diode, wherein the length between the light emitting diode and the fixture is similar for having a uniformed color light.

### FIELD OF THE INVENTION

The present invention relates to a device and method for manufacturing thereof, and more particularly to a light emitting device and method for manufacturing thereof that can be used to have uniformed color light.

### BACKGROUND

A Light emitting diode (LED) comprises advantages of long lifetime, small volume, low power consumption, high speed response time, non-heat radiation, and single color light emitting; therefore, it is applied in the fields of indication light, billboard, traffic lights, vehicle lamp, display panel, communication tool, consuming electrical production, and so on.

Since a white light has wider wavelength distribution and better color rendering then other color lights, it has been the most general light source regarding as the illuminant apparatus. However, the wavelength distribution of light source correlates with the crystal material regarding to the light emitting diode, that is, the structure of the specified crystal material regarding to the LED has only fixed wavelength distribution and color light, therefore, a light emitting diode that can be used to emit white light and be as an illuminant apparatus is the most important study field for all relative circles.

Referring to FIG. 1 is a cross sectional view of the prior art light emitting device. The light emitting device 10 comprises fluorescent layer 15 over a light emitting diode 13 disposed on a submount 11, wherein the fluorescent layer 15 is used to transform a partial color light generated by the light emitting diode 13 for having a white light source. For example, the fluorescent layer 15 comprises a yellow fluorescent powder, and the light emitting diode 13 can emit a blue light, wherein a partial blue light that passes through the fluorescent layer 15 can excite the yellow fluorescent powder for generating a yellow light to result the color light that has passed through the fluorescent layer 15 comprises the blue light and the yellow light, thus, the wavelength distribution of color light generated by the light emitting device 10 can be wider for having a white light source.

In addition, the brightness of the yellow light excited from the yellow powder is regarding to the thickness of the fluorescent layer 15 while the blue light is passing through the fluorescent layer 15. For example, as the thickness of the fluorescent layer 15 is thicker, the brightness of the yellow light that passes through the fluorescent layer 15 will be brighter, oppositely, the brightness of the blue light will be darker, such that the color of color light generated by the light emitting device 10 will be deflective yellow.

However, the thickness of the fluorescent layer 15 of the prior art light emitting device 10 is not uniform generally, that is, the thickness of the fluorescent layer 15 is different, wherein the color light of the light emitting diode 13 passes through the fluorescent layer 15; therefore, the color of the color light will vary with the emitting angle. For example, the thickness of the fluorescent layer 15 that is passed through by the first light L1 is thinner, and then the rate of the yellow light spreading field within the first light L1 will be smaller, on the contrary, the thickness of the fluorescent layer 15 that is passed through by the second light L2 is thicker, and then the rate of the yellow light spreading field within the first light L1 will be larger. Accordingly, the color of color light that is generated in each angle by the light emitting device 10 will be varied; for example, the color of color light is deflective yellow in a partial region, and the color of color light is deflective blue in another partial region, such that will result the usage field of the light emitting device 10 is limited.

### SUMMARY OF THE INVENTION

Accordingly, a novel light emitting device and method for manufacturing thereof are the key point of the present invention, which are not only used to improve the uniformity of color light generated by the light emitting device, but also simplify the manufacturing process of the light emitting device.

It is a primary object of the present invention to provide a light emitting device, wherein the thickness of the fluorescent layer is even, as well as, the color of color light generated by the light emitting diode is uniform, too.

It is a secondary object of the present invention to provide a method for manufacturing the light emitting device, wherein a fixture is used to form an inner space, such that the thickness of the fluorescent layer that covers the light emitting diode is uniform.

It is another object of the present invention to provide a method for manufacturing the light emitting device, wherein a fixture is used to form an inner space, and then a fluorescent layer is disposed into the inner space, thus, the manufacturing process of light emitting diode can be simplified.

To achieve the previous mentioned objects, the present invention provides a method for manufacturing a light emitting device, comprising the steps of: disposing a fixture on a submount to form an inner space; disposing at least one light emitting diode on the submount, wherein the light emitting diode is within the inner space; and disposing a fluorescent layer into the inner space to cover the light emitting diode.

To achieve the previous mentioned objects, the present invention provides a method for manufacturing a light emitting device, comprising the steps of: disposing at least one light emitting diode on a submount; disposing a fixture on the submount to form an inner space, wherein the light emitting diode is disposed within the inner space; and disposing a fluorescent layer into the inner space to cover the light emitting diode.

To achieve the previous mentioned objects, the present invention provides a light emitting device, comprising: a submount; a fixture disposed on the submount to form an inner space, wherein the fixture is made of a transparent material; at least one light emitting diode disposed within the inner space; and a fluorescent layer disposed into the inner space for covering the light emitting diode.

### BRIEF DESCRIPTION OF DRAWINGS

FIG. 1 is a cross section view of a prior art light emitting device.

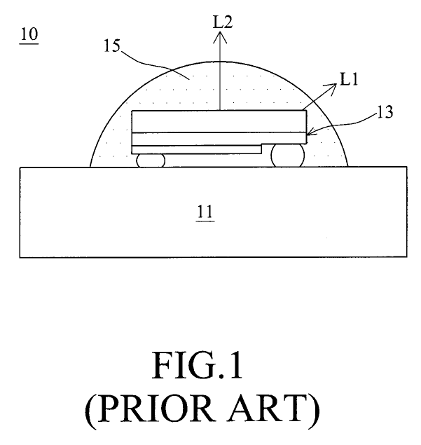

FIG. 2A, FIG. 2B and FIG. 3 are the cross section views of a preferred embodiment of the present invention a light emitting device with reference to each manufacturing step.

FIG. 4A is a cross section view of another embodiment of the present invention.

FIG. 4B is a top view of above embodiment of the present invention.

FIG. 5 is a cross section view of another embodiment of the present invention.

FIG. 6 is cross section view of another embodiment of the present invention.

### DETAILED DESCRIPTION

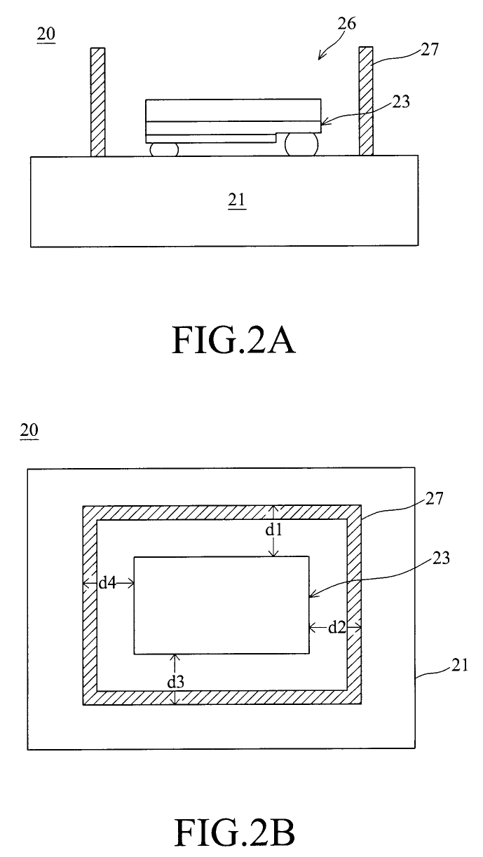

Referring to FIG. 2A, FIG. 2B and FIG. 3 are respectively the cross section views of a preferred embodiment of the present invention a light emitting device with reference to each manufacturing step. A fixture 27 is disposed on a submount 21 to form a inner space 26, and at least one light emitting diode 23 is disposed on the submount 21, wherein the light emitting diode 23 is within the inner space 26 formed by the fixture 26.

The manufacturing process of the fixture 27 and the light emitting diode 23 can be exchanged; for example, at least one light emitting diode 23 is disposed on the submount 21 first, and then the fixture 27 is disposed around the light emitting diode 23, thus, the light emitting diode 23 can be within the inner space 26 formed by the fixture 27, wherein the light emitting diode 23 can be disposed on the submount 21 in a flip chip configuration.

Of course, the manufacturing method of the fixture 27 can be tuned according to the material thereof is different. For example, the fixture 27 made by an injection molding or a grout molding connects with the submount 21 by an adhesive. Otherwise, the thermoforming material can be applied on a partial region of the submount 21 to form the fixture 27. In another embodiment, a frame with fixed shape can be placed on the submount 21 for forming a setting mold, as well as, a thermoforming material is filled into the setting mold for forming the fixture 27.

The relative position between the fixture 27 and the light emitting diode 23 can be adjusted, while the fixture 27 and the light emitting diode 23 are disposed on the submount. For example, once the fixture 27 comprises a fluorescent material, the length d1, d2, d3 and d4 of each side surface of light emitting diode 23 and out surface of the fixture 27 that is near each side surface of the light emitting diode 23 are similar, thus, the light emitting diode 23 should be disposed on the center of the inner space 26.

After finishing the manufacturing process of the light emitting diode 23 and the fixture 27, a fluorescent layer 25 is disposed into the inner space 26 to cover the light emitting diode 23. The height of the fixture 27 or the size of the inner space 26 can be changed for adjusting the length d5 between the top surface of the light emitting diode 23 and the top of the fluorescent layer 25. For example, once the fixture 27 comprises a fluorescent material, the length d5 between the top surface of the light emitting diode 23 and the top of the fluorescent layer 25 is similar to the length d2, d1, d3 or d4 of each side surface of the light emitting diode 23 and the out surface of the fixture 27.

Thereafter, as the color light generated by the light emitting diode 23 passes through the fluorescent layer 25, a partial color light can be transformed into other color lights. For example, as a blue light that is generated by the light emitting diode 23 passes through the fluorescent layer 25 that comprises a yellow fluorescent material, a partial blue light that excites the yellow fluorescent material can be transformed into a yellow light, such that the wavelength distribution of the color light generated by the light emitting device 20 can be wilder for having a white light source.

In the embodiment of the present invention, the fixture 27 can comprise a fluorescent material; for example, the silicon or the epoxy is mixed with the fluorescent material for having the fixture 27. As the color light generated by the light emitting diode 23 passes through the fixture 27, a partial color light can excite the fluorescent material of the fixture 27 for transforming the color thereof. For example, as a blue light that is generated by the light emitting diode 23 passes through the fixture 27 that comprises a yellow fluorescent material, a partial blue light that excites the yellow fluorescent material can be transformed into a yellow light.

Practically, as the color light generated by the light emitting diode 23 passes through the fluorescent layer 25 and the fixture 27, the fluorescent material of the fluorescent layer 25 and the fixture 27 can be excited by the color light to transform the color of the color light; such as, the original color light that is a blue light can be transformed to become a yellow light. Furthermore, the length d1, d2, d3 and d4 of each side surface of the light emitting diode 23 and the out surface of the fixture 27 which is near each side surface of the light emitting diode 23 are similar, and the length d5 between the top surface of the light emitting diode 23 and the top of the fluorescent layer 25 is similar to the length d1, d2, d3 and d4. Therefore, the color light generated from the light emitting diode 23 can pass through similar length of the fluorescent layer 25 and the fixture 27, and excite similar amount of the fluorescent material for uniforming the color of color light; for example, the rate of blue light and yellow light of the color light generated by the light emitting device 20 is similar at each angle.

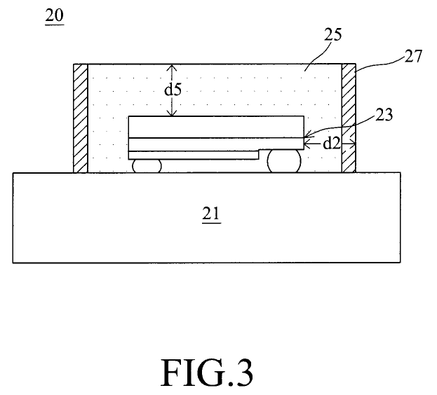

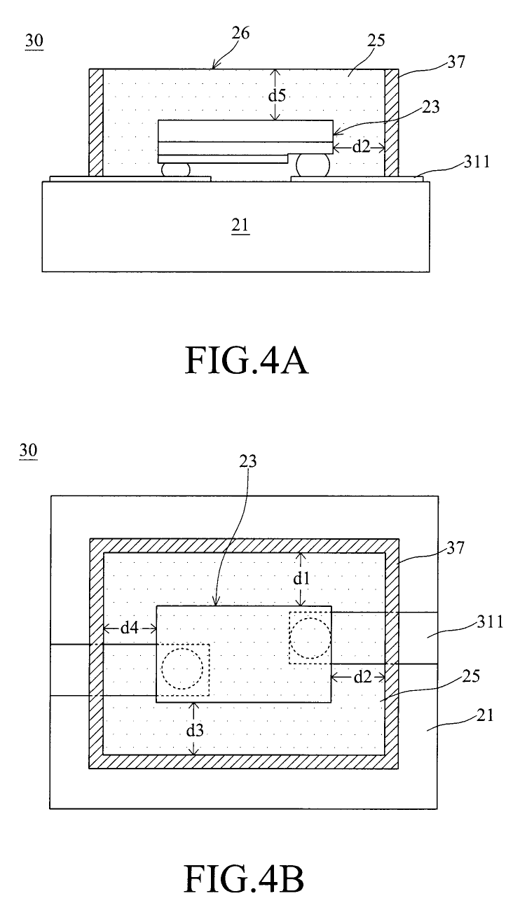

Referring to FIG. 4A and FIG. 4B are respectively a cross section view and top view of another embodiment of the present invention. At least one light emitting diode 23 and a fixture 37 are disposed on the submount 21, wherein the light emitting diode 23 is disposed on the center of the inner space 26 formed by the fixture 37. In accordance with the present invention, the fixture 37 without the fluorescent material is made of a transparent material, such as epoxy, silicone, glass, plastic (PC), or acrylics.

When the light emitting diode 23 and the fixture 37 have be disposed on the submount 21, a fluorescent layer 25 can be disposed into the inner space 26 for covering the light emitting diode 23 uniformly. The submount 21 comprises at least one conductive lead 311, and the light emitting diode 23 is disposed on the conductive lead 311 in a flip chip configuration.

The relative position between the fixture 27 and the light emitting diode 23 can be adjusted, while the fixture 27 and the light emitting diode 23 are disposed on the submount 37, such that the length d1, d2, d3 and d4 of each side surface of the light emitting diode 23 and the inner surface of the fixture 37 which is near each side surface of the light emitting diode 23 are similar. Since the fixture 37 is made of a transparent material, the length d5 between the top surface of the light emitting diode 23 and top of the fluorescent layer 25 is similar to the length d1, d2, d3 or d4. Therefore, the color light generated by the light emitting diode 23 passes through the fluorescent layer 25 with similar length, thus, the light emitting device 30 has uniform color light.

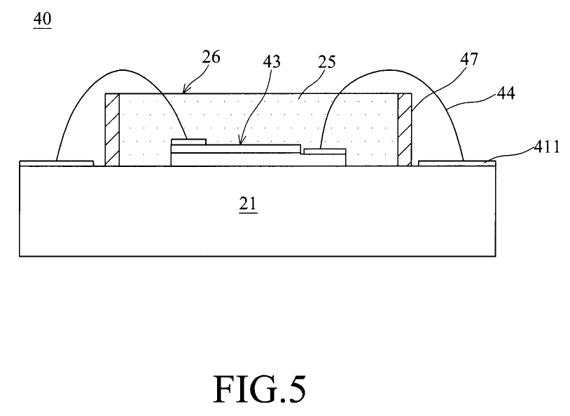

Referring to FIG. 5 is cross section view of another embodiment of the invention. The light emitting device 40 comprises at least one light emitting diode 43 disposed on the submount 21, wherein the light emitting diode 43 that is not provided in accordance with a flip chip type is electrically connected with the conductive lead 411 by the wire bonding process. For example, the light emitting diode 42 is electrically connected with the conductive lead 411 via a conductive wire 44, wherein the conductive lead 411 is disposed on the submount 21 that is provided on the external of the fixture 47.

After finishing the wire bonding process of the light emitting diode 43 and the conductive wire 411, a fluorescent layer 25 is disposed into the fixture 47. The fixture 47 is made of a transparent material in an embodiment of the invention, on the contrary, the fixture 47 comprises a fluorescent material in another embodiment of the invention, and then the length between the fixture 47 and the light emitting diode 43, the height of the fixture 47, and the thickness of the fluorescent layer 25 can be adjusted according to the material of the fixture 47; for example, the fixture 47 comprises a fluorescent material or not.

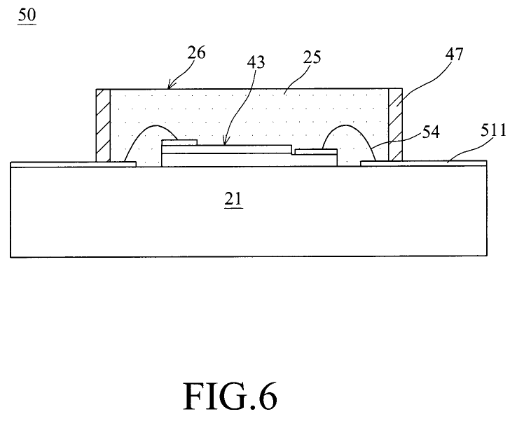

Referring to the FIG. 6, is a cross section view of another embodiment of the invention. Comparatively, the light emitting device 50 further comprises at least one conductive lead 511 extending to the inner space 26, thus, the conductive wire 54 that connects with the light emitting diode 43 and the conductive lead 511 is within the inner space 26, and the fluorescent layer can cover the light emitting diode 43 and the conductive wire 54.

In above embodiment of the invention, the submount 21 can be a lead frame that has advantage of disposing the fluorescent layer 25 and uniforming the color of color light of the light emitting device, too. The fixture can be made of an opaque material. Besides, the shape of the light emitting diode and the fixture is square in above embodiment of the invention, but the shape of the light emitting diode and the fixture can be changed as a polygon.

While this invention has been described with reference to illustrative embodiments, this description is not intended to be construed in a limiting sense. Various modifications of the illustrative embodiments, as well as other embodiments of the invention, which are apparent to persons skilled in the art to which the invention pertains are deemed to lie within the spirit and scope of the invention.

1. A method for manufacturing a light emitting device, comprising the steps of:
disposing a fixture on a submount to form an inner space;
disposing at least one light emitting diode on said submount, wherein said light emitting diode is within said inner space; and
disposing a fluorescent layer into said inner space to cover said light emitting diode.

2. The method of claim 1, wherein said fixture is made of a transparent material.

3. The method of claim 2, wherein the length between each side surface of said light emitting diode and inside surface of said fixture are similar.

4. The method of claim 3, wherein said length is similar to the length between the top surface of said light emitting diode and the top of said fluorescent layer.

5. The method of claim 1, wherein said fixture comprises a fluorescent material.

6. The method of claim 5, wherein the length between each side surface of said light emitting diode and out surface of said fixture are similar.

7. The method of claim 6, wherein said length is similar to the length between the top surface of said light emitting diode and the top of said fluorescent layer.

8. The method of claim 1, wherein said light emitting diode is disposed on said submount in a flip chip configuration.

9. The method of claim 1, wherein said submount comprises at least one conductive lead that is electrically connected with said light emitting diode by a wire bonding process.

10. The method of claim 1, wherein said light emitting diode is disposed on the center of said fixture.

11. A method for manufacturing a light emitting device, comprising the steps of:
disposing at least one light emitting diode on a submount;
disposing a fixture on said submount to form an inner space, wherein said light emitting diode is disposed within said inner space; and
disposing a fluorescent layer into said inner space to cover said light emitting diode.

12. A light emitting device, comprising:
a submount;
a fixture disposed on said submount to form an inner space, wherein said fixture is made of a transparent material;
at least one light emitting diode disposed within said inner space; and
a fluorescent layer disposed into said inner space for covering said light emitting diode.

13. The light emitting device of claim 12, wherein said light emitting diode is disposed on said submount in a flip chip configuration.

14. The light emitting device of claim 12, wherein said submount comprises at least one conductive lead that is electrically connected with said light emitting diode via at least one conductive wire.

15. The light emitting device of claim 12, wherein the length between each side surface of said light emitting diode and inside surface of said fixture are similar.

16. The light emitting device of claim 15, wherein said length is similar to the length between the top surface of said light emitting diode and the top of said fluorescent layer.

17. The light emitting device of claim 12, wherein said fixture comprises a fluorescent material.

18. The light emitting device of claim 17, wherein the length between each side surface of said light emitting diode and out surface of said fixture are similar.

19. The light emitting device of claim 18, wherein said length is similar to the length between the top surface of said light emitting diode and the top of said fluorescent layer.

20. The light emitting device of claim 12, wherein said light emitting diode is disposed on the center of said inner space.
